(19) United States
(12) Patent Application Publication
(10) Pub. No.: US 2025/0021001 A1
(43) Pub. Date: Jan. 16, 2025

(54) PHOTOSENSITIVE RESIN COMPOSITION, PHOTOSENSITIVE RESIN LAYER USING THE SAME, DISPLAY DEVICE, AND MANUFACTURING METHOD OF PHOTOSENSITIVE RESIN LAYER

(71) Applicant: SAMSUNG SDI CO., LTD., Yongin-si (KR)

(72) Inventors: DONGHYUN PARK, Suwon-si (KR); Juho JUNG, Suwon-si (KR); Jieun KIM, Suwon-si (KR); Jihong KIM, Suwon-si (KR); Seungbeom KEE, Suwon-si (KR); Baek Soung PARK, Suwon-si (KR)

(21) Appl. No.: 18/757,804

(22) Filed: Jun. 28, 2024

(30) Foreign Application Priority Data
Jul. 7, 2023 (KR) 10-2023-0088563
Apr. 29, 2024 (KR) 10-2024-0056932

(51) Int. Cl. G03F 7/033; G03F 7/00; H10K 59/38

(52) U.S. Cl. CPC G03F 7/033; G03F 7/0007; H10K 59/38

(57) ABSTRACT

An antioxidant-free photosensitive resin composition including a binder resin; a colorant; a polymerizable monomer; a polymerization initiator; and a solvent, wherein the colorant is included in an amount of about 80 wt % to about 95 wt %, based on a total weight of the composition, the polymerization initiator is included in an amount of about 0.65 wt % to about 1.3 wt %, based on a total weight of the composition, the colorant comprises a green pigment and a yellow pigment, and the green pigment is included in an amount of greater than or equal to about 50 wt %, based on a total weight of the colorant.

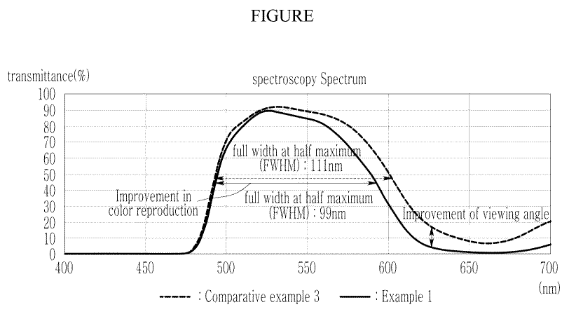

### CROSS-REFERENCE TO RELATED APPLICATION

This application claims priority to and the benefit of Korean Patent Application No. 10-2023-0088563 filed in the Korean Intellectual Property Office on Jul. 7, 2023, and Korean Patent Application No. 10-2024-0056932 filed in the Korean Intellectual Property Office on Apr. 29, 2024, the entire contents of which are incorporated herein by reference.

### BACKGROUND

### 1. Field

Embodiments relate to a photosensitive resin composition, a photosensitive resin layer using the same, a display device, and a method of manufacturing the photosensitive resin layer.

### 2. Description of the Related Art

Recently, as display panels applied to VR (Virtual Reality), AR (Augmented Reality), and MR (Mixed Reality) devices, interests in self-luminous micro OLED display panels, which emit light on their own, are increasing.

### SUMMARY

The embodiments may be realized by providing an antioxidant-free photosensitive resin composition including a binder resin; a colorant; a polymerizable monomer; a polymerization initiator; and a solvent, wherein the colorant is included in an amount of about 80 wt % to about 95 wt %, based on a total weight of the composition, the polymerization initiator is included in an amount of about 0.65 wt % to about 1.3 wt %, based on a total weight of the composition, the colorant comprises a green pigment and a yellow pigment, and the green pigment is included in an amount of greater than or equal to about 50 wt %, based on a total weight of the colorant.

The green pigment and yellow pigment may each independently be included in a form of a pigment dispersion.

The binder resin may be an acrylic binder resin.

The acrylic binder resin may have an acid value of greater than or equal to about 50 KOHm/g and a weight average molecular weight of less than or equal to about 7,000 g/mol.

The acrylic binder resin may have a double bond equivalent weight of greater than or equal to about 360 g/mol.

The polymerizable monomer may include a compound that comprises three or more functional groups.

The polymerizable monomer may include a mixture of two different compounds, and the two different compounds may be each independently a compound comprising three or more functional groups.

The two different compounds may be mixed in a weight ratio of about 1:1.

An amount of the polymerizable monomer included in the composition may be larger than an amount of the binder resin included in the composition.

The photosensitive resin composition may have a full width at half maximum (FWHM) of less than 105 nm.

The photosensitive resin composition may have a transmittance of less than about 8% at 630 nm.

The photosensitive resin composition may include about 1 wt % to about 5 wt % of the binder resin; the about 80 wt % to about 95 wt % of the colorant; about 1 wt % to about 10 wt % of the polymerizable monomer; the about 0.65 wt % to about 1.3 wt % of the polymerization initiator; and the solvent, based on a total weight of the photosensitive resin composition.

The photosensitive resin composition may further include malonic acid, 3-amino-1,2-propanediol, a silane coupling agent, a leveling agent, a surfactant, or a combination thereof.

The embodiments may be realized by providing a photosensitive resin layer manufactured using the photosensitive resin composition according to an embodiment.

The embodiments may be realized by providing a display device comprising the photosensitive resin layer according to an embodiment.

The display device may be a micro OLED display device that includes an OLED substrate on a silicon wafer and a color filter layer stacked on the OLED substrate, the color filter layer being configured to convert white light generated from the OLED substrate into a plurality of color lights, and the color filter layer may include a red color filter, a green color filter, and a blue color filter.

The embodiments may be realized by providing a method of manufacturing a photosensitive resin layer, the method including coating the photosensitive resin composition according to an embodiment on a substrate; prebaking at a temperature of about 100° C. or lower after coating; exposing to i-line after the prebaking, and developing after exposing.

### BRIEF DESCRIPTION OF THE DRAWING

Features will be apparent to those of skill in the art by describing in detail exemplary embodiments with reference to the attached drawing in which:

the FIGURE is a graph showing the spectral spectra of the photosensitive resin compositions according to Example 1 and Comparative Example 3.

### DETAILED DESCRIPTION

Example embodiments will now be described more fully hereinafter with reference to the accompanying drawing; however, they may be embodied in different forms and should not be construed as limited to the embodiments set forth herein. Rather, these embodiments are provided so that this disclosure will be thorough and complete, and will fully convey exemplary implementations to those skilled in the art.

It will also be understood that when a layer or element is referred to as being “on” another layer or element, it can be directly on the other layer or element, or intervening layers may also be present. In addition, it will also be understood that when a layer is referred to as being “between” two layers, it can be the only layer between the two layers, or one or more intervening layers may also be present. As used herein, the term “or” is not necessarily an exclusive term, e.g., “A or B” would include A, B, or A and B.

As used herein, when specific definition is not otherwise provided, “alkyl group” refers to a C1 to C20 alkyl group, “alkenyl group” refers to a C2 to C20 alkenyl group, “cycloalkenyl group” refers to a C3 to C20 cycloalkenyl group, “heterocycloalkenyl group” refers to a C3 to C20 heterocycloalkenyl group, “aryl group” refers to a C6 to C20 aryl group, “arylalkyl group” refers to a C6 to C20 arylalkyl group, “alkylene group” refers to a C1 to C20 alkylene group, “arylene group” refers to a C6 to C20 arylene group, “alkylarylene group” refers to a C6 to C20 alkylarylene group, “heteroarylene group” refers to a C3 to C20 heteroarylene group, and “alkoxylene group” refers to a C1 to C20 alkoxylene group.

As used herein, when specific definition is not otherwise provided, “substituted” refers to replacement of at least one hydrogen by a substituent selected from a halogen atom (F, Cl, Br, or I), a hydroxy group, a C1 to C20 alkoxy group, a nitro group, a cyano group, an amine group, an imino group, an azido group, an amidino group, a hydrazino group, a hydrazono group, a carbonyl group, a carbamyl group, a thiol group, an ester group, an ether group, a carboxyl group or a salt thereof, a sulfonic acid group or a salt thereof, a phosphoric acid group or a salt thereof, a C1 to C20 alkyl group, a C2 to C20 alkenyl group, a C2 to C20 alkynyl group, a C6 to C20 aryl group, a C3 to C20 cycloalkyl group, a C3 to C20 cycloalkenyl group, a C3 to C20 cycloalkynyl group, a C2 to C20 heterocycloalkyl group, a C2 to C20 heterocycloalkenyl group, a C2 to C20 heterocycloalkynyl group, a C3 to C20 heteroaryl group, or a combination thereof.

As used herein, when specific definition is not otherwise provided, “hetero” means that at least one hetero atom of N, O, S, and P is included in the chemical formula.

As used herein, when specific definition is not otherwise provided, “(meth)acrylate” refers to “acrylate” and “methacrylate” and “(meth)acrylic acid” refers to “acrylic acid” and “methacrylic acid.”

As used herein, when a definition is not otherwise provided, the term “combination” refers to mixing or copolymerization. In addition, “copolymerization” refers to block copolymerization to random copolymerization, and “copolymer” refers to a block copolymer to a random copolymer.

In the chemical formula of the present specification, unless a specific definition is otherwise provided, hydrogen is bonded at the position when a chemical bond is not drawn where supposed to be given. As used herein, hydrogen substitution (-H) may include deuterium substitution (-D) or tritium substitution (-T). For example, any hydrogen in any compound described herein may be protium, deuterium, or tritium (e.g., based on natural or artificial substitution).

As used herein, when a definition is not otherwise provided, “*” indicates a point where the same or different atom or chemical formula is linked.

A photosensitive resin composition according to some embodiments may not include an antioxidant (e.g., may not intentionally include an antioxidant, and may be entirely free of antioxidant or only include only trace or otherwise insignificant amounts of an antioxidant), and may include, as an antioxidant-free composition, e.g., (A) a binder resin; (B) a colorant; (C) a polymerizable monomer; (D) a polymerization initiator; and (E) a solvent. In an implementation, the colorant and the polymerization initiator may be included in an amount of about 80 wt % to about 95 wt % and about 0.65 wt % to about 1.3 wt %, respectively, based on a total weight of the composition. In an implementation, the colorant may include a green pigment and a yellow pigment. In an implementation, the green pigment may be included in an amount of greater than or equal to about 50 wt %, based on a total weight of the colorant.

Some color photoresists, e.g., a negative photosensitive liquid material implemented into red, green, and blue patterns, have been technologically developed in the direction of gradually modifying a composition of the liquid material. For example, attempts to improve color purity may include modifying a type or content of pigment dispersion, which is a coloring material implementing a color pattern, improving patternability by modifying a composition of a binder resin or a photopolymerization initiator, or improving coating property and color uniformity by using other additives such as a leveling agent or the like.

The embodiments relate to a photosensitive resin composition applied to a color filter process used in a micro OLED display device, e.g., a green photosensitive resin composition applied to a green color filter process.

The micro OLED refers to WOLED (White OLED) deposited on a silicon wafer. It is also called OLEDoS (Organic Light Emitting Diode on Silicon). The micro OLED display device refers to a display device applied on the micro OLED.

With the advance of the 4^{th} industrial revolution era, as a metaverse market is rapidly growing, development of display devices which increase reality and visibility of AR, VR, and MR devices but minimize dizziness has been considered. For this purpose, several candidate technologies, e.g., LCoS (Liquid Crystal on Silicon), LEDoS (Light Emitting Diode on Silicon), OLEDoS (Organic Light Emitting Diode on Silicon), or the like have been considered. The OLEDoS technology, which may have advantages of a high contrast ratio, a fast response speed, and self-emission to reduce a volume and weight of a device to a relatively simple optical system, is being developed in many fields.

OLEDoS includes the formation of very small pixels of several micrometer units to realize a micro display with a high resolution, compared with other displays, and formation of color filters through a low-temperature process to avoid damaging the lower OLED, which could cause issues in the development.

One or more embodiments may provide a photosensitive resin composition prepared by controlling each content of a colorant and a polymerization initiator and furthermore controlling a content of a green pigment in the colorant but not including an antioxidant to achieve low-temperature curing and micro-patterning, completing the photosensitive resin composition achieving the micro-patterning and securing excellent color uniformity as well as being curable at a low temperature of about 100° C. or lower, and accordingly, the photosensitive resin composition according to some embodiments due to these characteristics may be applied to display devices for VR (Virtual Reality), AR (Augmented Reality), and MR (Mixed Reality), which are next-generation displays, for example, micro OLED display devices.

Hereinafter, each component is described in detail.

### (A) Binder Resin

The binder resin may include an acrylic binder resin. In an implementation, the binder resin may be an acrylic binder resin.

The acrylic binder resin may be a copolymer of a first ethylenic unsaturated monomer and a second ethylenic unsaturated monomer that is copolymerizable therewith, and may be a resin including at least one acrylic repeating unit.

The first ethylenic unsaturated monomer may be an ethylenic unsaturated monomer including at least one carboxyl group. Examples of the monomer may include (meth)acrylic acid, maleic acid, itaconic acid, fumaric acid, or a combination thereof.

The first ethylenic unsaturated monomer may be included in an amount of about 5 wt % to about 50 wt %, e.g. about 10 wt % to about 40 wt %, based on a total weight of the acrylic binder resin.

The second ethylenic unsaturated monomer may be an aromatic vinyl compound, e.g., styrene, α-methylstyrene, vinyl toluene, vinylbenzylmethylether or the like; an unsaturated carboxylate ester compound, e.g., methyl(meth)acrylate, ethyl(meth)acrylate, butyl(meth)acrylate, 2-hydroxyethyl(meth)acrylate, 2-hydroxy butyl(meth)acrylate, benzyl(meth)acrylate, cyclohexyl(meth)acrylate, phenyl(meth)acrylate, or the like; an unsaturated amino alkyl carboxylate ester compound, e.g., 2-aminoethyl(meth)acrylate, 2-dimethylaminoethyl(meth)acrylate, or the like; a carboxylic acid vinyl ester compound, e.g., vinyl acetate, vinyl benzoate, or the like; an unsaturated glycidyl carboxylate ester compound, e.g., glycidyl(meth)acrylate or the like; a vinyl cyanide compound, e.g., (meth)acrylonitrile or the like; an unsaturated amide compound, e.g., (meth)acrylamide or the like; or the like, and may be used alone or as a mixture of two or more.

Examples of the acrylic binder resin may include a (meth)acrylic acid/benzylmethacrylate copolymer, a (meth)acrylic acid/benzylmethacrylate copolymer, a (meth)acrylic acid/benzylmethacrylate/styrene copolymer, a (meth)acrylic acid/benzylmethacrylate/2-hydroxyethylmethacrylate copolymer, a (meth)acrylic acid/benzylmethacrylate/styrene/2-hydroxyethylmethacrylate copolymer, and the like, and these may be used alone or as a mixture of two or more.

The acrylic binder resin may have a weight average molecular weight of less than or equal to about 7,000 g/mol, e.g., about 3,000 g/mol to about 7,000 g/mol, and an acid value of greater than or equal to about 50 KOHm/g, e.g., about 50 KOHm/g to about 90 KOHm/g or about 60 KOHm/g to about 80 KOHm/g, and may have a double bond equivalent weight of greater than or equal to about 360 g/mol. Maintaining the weight average molecular weight, acid value, and double bond equivalent of the acrylic binder resin within the above ranges may help ensure that excellent pattern formation properties can be achieved, and the produced thin film can have excellent mechanical and thermal properties.

In an implementation, the binder resin may further include an epoxy binder resin.

The binder resin may help improve heat resistance by further including an epoxy binder resin. The epoxy binder resin may be, e.g., a phenol novolac epoxy resin, a tetramethyl biphenyl epoxy resin, a bisphenol A epoxy resin, a bisphenol F epoxy resin, an alicyclic epoxy resin, or a combination thereof.

In an implementation, the binder resin including the epoxy binder resin may help secure dispersion stability of a colorant such as a pigment, which will be described below, and may help form a pixel having a desired resolution during a developing process.

The epoxy binder resin may be included in an amount of about 1 wt % to about 10 wt %, e.g., about 5 wt % to about 10 wt %, based on a total weight of the binder resin. Maintaining the amount of the epoxy binder resin within the above ranges, film residue ratio and chemical resistance may be greatly improved.

An epoxy equivalent weight of the epoxy resin may be about 150 g/eq to about 200 g/eq. Including an epoxy binder resin having an epoxy equivalent within the above range in the binder resin may help ensure that there is an advantageous effect in improving a curing degree of the formed pattern and fixing the colorant in the structure in which the pattern is formed.

The binder resin may be included in an amount of about 1 wt % to about 5 wt %, e.g., about 1 wt % to about 4 wt %, or about 2 wt % to about 4 wt %, based on a total weight of the photosensitive resin composition. Maintaining the amount of the binder resin within the above ranges may help ensure that excellent sensitivity, developability, resolution, and linearity of the pattern can be obtained.

### (B) Colorant

The photosensitive resin composition according to some embodiments may be a green photosensitive resin composition. In an implementation, the colorant in the composition may include a green pigment and a yellow pigment.

The green pigment may be, e.g., C.I. Green Pigment 7, C.I. Green Pigment 36, C.I. Green Pigment 58, C.I. Green Pigment 59, or the like in the color index, which may be used alone or in a mixture of two or more.

The yellow pigment may be, e.g., an isoindoline pigment such as C.I. Yellow Pigment 185, C.I. Yellow Pigment 139, or the like, a quinophthalone pigment such as C.I. Yellow Pigment 138, or a nickel complex pigment such as C.I. Yellow Pigment 150 in the color index, which may be used alone or in a mixture of two or more.

In an implementation, the green pigment may be included in a greater weight than the yellow pigment. In an implementation, the green pigment may be included in an amount of greater than or equal to about 50 wt %, based on a total weight of the colorant. In an implementation, the colorant including the green pigment and the yellow pigment may be included in the composition in an amount of about 80 wt % to about 95 wt %, e.g., about 80 wt % to about 90 wt %, or about 80 wt % to about 85 wt %, based on the total weight of the photosensitive resin composition. Within the above amounts, the full width at half maximum (FWHM) may be narrowed, the color gamut may be increased, and the transmittance at 630 nm may be reduced, making it very easy to achieve the effect of improving the viewing angle.

In an implementation, the photosensitive resin composition according to some embodiments may have a full width at half maximum (FWHM) of less than 105 nm, and thus may be advantageous in increasing color gamut.

In an implementation, the photosensitive resin composition according to some embodiments may have a transmittance of less than about 8% at 630 nm, and thus may have an excellent viewing angle improvement effect.

In an implementation, the colorant may further include a violet pigment or the like, in addition to the green pigment and yellow pigment.

The violet pigment may be, e.g., C.I. Violet Pigment 23 (V.23), C.I. Violet Pigment 29, Dioxazine Violet, First Violet B, Methyl Violet Lake, Indanethrene Brilliant Violet, or the like in the color index, which may be used alone or in a mixture of two or more.

The pigments may be used alone or in a mixture of two or more.

The pigment may be used after pre-treatment using a water-soluble inorganic salt and a wetting agent. In an implementation, the pigment may be used after the pre-treatment, and the average particle diameter of the pigment may become finer.

The pre-treatment may be performed by kneading the pigment with a water-soluble inorganic salt and a wetting agent and then, filtering and washing the knead pigment.

The kneading may be performed at a temperature ranging from about 40° C. to about 100° C., and the filtering and washing may be performed by filtering the pigment after washing away an inorganic salt with water or the like.

Examples of the water-soluble inorganic salt may include sodium chloride, potassium chloride, and the like. The wetting agent may make the pigment to be uniformly mixed with the water-soluble inorganic salt uniformly and be pulverized. Examples of the wetting agent may include alkylene glycol monoalkyl ethers such as ethylene glycol monoethylether, propylene glycol monomethylether, diethylene glycol monomethylether, and the like, and alcohols such as ethanol, isopropanol, butanol, hexanol, cyclohexanol, ethylene glycol, diethylene glycol, polyethylene glycol, glycerine polyethylene glycol, and the like. These may be used alone or in combination of two or more.

The pigment, after the kneading, may have an average particle diameter of about 5 nm to about 200 nm, e.g. about 5 nm to about 150 nm. Maintaining the average particle diameter of the pigment within the above ranges may help ensure that stability in the pigment mill base (pigment dispersion) is excellent, and there may be no concern about deterioration of pixel resolution.

The pigment, such as the green pigment and yellow pigment, may each independently be used together with a dispersant and a solvent in the form of a pigment dispersion, such as a mill base.

The dispersant may help the pigment to be uniformly dispersed in the dispersion, and nonionic, anionic or cationic dispersants may be used, respectively. In an implementation, polyalkylene glycol or its ester, polyoxy alkylene, a polyhydric alcohol ester alkylene oxide adduct, an alcohol alkylene oxide adduct, sulfonic acid ester, sulfonic acid salt, carboxylic acid ester, carboxylic acid salt, alkyl amide alkylene oxide adduct, an alkylamine, or the like, may be used, and these may be used alone or in combination of two or more.

Commercially available examples of the dispersant may include DISPERBYK-101, DISPERBYK-130, DISPERBYK-140, DISPERBYK-160, DISPERBYK-161, DISPERBYK-162, DISPERBYK-163, DISPERBYK-164, DISPERBYK-165, DISPERBYK-166, DISPERBYK-170, DISPERBYK-171, DISPERBYK-182, DISPERBYK-2000, DISPERBYK-2001, and the like made by BYK Co., Ltd.; EFKA-47, EFKA-47EA, EFKA-48, EFKA-49, EFKA-100, EFKA-400, EFKA-450, and the like made by EFKA Chemicals Co.; Solsperse 5000, Solsperse 12000, Solsperse 13240, Solsperse 13940, Solsperse 17000, Solsperse 20000, Solsperse 24000GR, Solsperse 27000, Solsperse 28000, and the like made by Zeneka Co.; or PB711, or PB821 made by Ajinomoto Inc.

The dispersant may be included in an amount of about 0.1 wt % to about 15 wt %, based on a total weight of the photosensitive resin composition. Within the above range, the dispersibility of the composition may be excellent, and thus stability, developability and patternability may be excellent when manufacturing a photosensitive resin layer.

This pigment dispersion may further include a dispersion aid, a dispersion resin in addition to the pigment, the dispersant, and the (dispersion) solvent. The solid pigment may be included in an amount of about 5 wt % to about 20 wt %, e.g., about 8 wt % to about 15 wt %, based on a total weight of the pigment dispersion.

(Dispersion) solvents for the pigment dispersion may include ethylene glycol acetate, ethyl cellosolve, propylene glycol methyl ether acetate, ethyl lactate, polyethylene glycol, cyclohexanone, propylene glycol methyl ether, or the like. In an implementation, the solvent may include propylene glycol methyl ether acetate.

The dispersion resin may be an acrylic resin including a carboxy group, which may help improve stability of the pigment dispersion and also help improve pixel patternability.

The colorant may include the pigment and may further include a dye, and in this case, the photosensitive resin composition of some embodiments may be a hybrid type composition. In an implementation, the dye may include a metal complex dye.

The metal complex dye may be a compound having maximum absorbance in the wavelength range of 200 nm to 650 nm. In an implementation, the compound may have absorbance in the above range in order to match the color coordinates to the combination of dyes, and the metal complex dye of all colors that dissolves in an organic solvent may be used.

In an implementation, the metal complex dye may be a green dye having maximum absorbance in a wavelength range of 530 nm to 680 nm, a yellow dye having maximum absorbance in a wavelength range of 200 nm to 400 nm, an orange dye having a maximum absorbance in a wavelength range of 300 nm to 500 nm, a red dye having maximum absorbance in a wavelength range of 500 nm to 650 nm, or a combination thereof.

The metal complex dye may be a direct dye, an acidic dye, a basic dye, an acidic mordant dye, a sulfide dye, a reduction dye, an azoic dye, a dispersion dye, a reactive dye, an oxidation dye, an oil-soluble dye, an azo dye, an anthraquinone dye, an indigoid dye, a carbonium ion dye, a phthalocyanine dye, a nitro dye, a quinoline dye, a cyanine dye, a polymethine dye, or a combination thereof.

The metal complex dye may include a metal ion, e.g., Mg, Ni, Cu, Co, Zn, Cr, Pt, Pd, or Fe.

The metal complex dye may be a complex of C.I. Solvent Dye such as C.I. Solvent Green 1, 3, 4, 5, 7, 28, 29, 32, 33, 34, 35, or the like; C.I. Acid Dye such as C.I. Acid Green 1, 3, 5, 6, 7, 8, 9, 11, 13, 14, 15, 16, 22, 25, 27, 28, 41, 50, 50:1, 58, 63, 65, 80, 104, 105, 106, 109, or the like; C.I. Direct Dye such as C.I. Direct Green 25, 27, 31, 32, 34, 37, 63, 65, 66, 67, 68, 69, 72, 77, 79, 82, or the like; C.I. Basic Dye such as C.I. Basic Green 1, or the like; C.I. Mordant Dye such as C.I. Mordant Green 1, 3, 4, 5, 10, 13, 15, 19, 21, 23, 26, 29, 31, 33, 34, 35, 41, 43, 53, or the like; C.I. Green pigments such as Pigment Green 7, 36, 58, or the like; Solvent Yellow 19, Solvent Yellow 21, Solvent Yellow 25, Solvent Yellow 79, Solvent Yellow 82, Solvent Yellow 88, Solvent Orange 45, Solvent Orange 54, Solvent Orange 62, Solvent Orange 99, Solvent Red 8, Solvent Red 32, Solvent Red 109, Solvent Red 112, Solvent Red 119, Solvent Red 124, Solvent Red 160, Solvent Red 132, or Solvent Red 218, and the metal ion.

The metal complex dye may have a solubility of greater than or equal to about 5, e.g., about 5 to about 10, in a solvent used in the photosensitive resin composition according to some embodiments, as described below. The solubility may be obtained by an amount (g) of the dye dissolved in 100 g of the solvent. Maintaining the solubility of the metal complex dye within the above ranges may help ensure that compatibility with other components constituting the photosensitive resin composition according to some embodiments and coloring power may be secured, and precipitation of the dye may be prevented.

The solvent may be, e.g., propylene glycol monomethyl ether acetate (PGMEA), ethyl lactate (EL), ethylene glycol ethyl acetate (EGA), cyclohexanone, 3-methoxy-1-butanol, or a combination thereof.

The metal complex dye may be included in an amount of about 0.01 wt % to about 1 wt %, e.g., about 0.01 wt % to about 0.5 wt %, based on a total weight of the photosensitive resin composition. Within the above ranges, high luminance and contrast ratio can be exhibited in a desired color coordinate.

In an implementation, the dye and the pigment may be mixed and used, and they may be mixed in a weight ratio of about 0.1:99.9 to about 99.9:0.1, e.g., about 1:9 to about 9:1. Mixing within the above weight ratio ranges may help ensure that chemical resistance and maximum absorption wavelength may be controlled within an appropriate range, and high luminance and contrast ratio may be exhibited in a desired color coordinate.

In an implementation, the colorant may be included in an amount of about 80 wt % to about 95 wt %, e.g., about 80 wt % to about 90 wt %, or about 80 wt % to about 85 wt %, based on a total weight of the photosensitive resin composition. Including the colorant in a very high content, i.e., the ranges, as described above, coloring effect and developability may be excellent in the micro OLED display device, making it easy to secure high color gamut and viewing angle characteristics.

### (C) Polymerizable Monomer

The polymerizable monomer in the photosensitive resin composition according to some embodiments may include a compound including three or more functional groups. In an implementation, the functional group may be a (meth)acrylate group, an epoxy group, or the like.

The photosensitive resin composition according to some embodiments has been developed for use in micro OLED display devices, and a low-temperature curing process may be used. In an implementation, in the case of low-temperature curing pattern processes, the contribution of thermal curing may be reduced and the influence of photocuring may increase. Accordingly, maximizing photocuring efficiency may be advantageous for securing excellent patternability under low-temperature curing. In an implementation, photocuring efficiency may be maximized by using a compound having at least three functional groups in the monomer as a polymerizable monomer. In an implementation, the photocuring efficiency may be affected by the weight average molecular weight of the polymerizable monomer and the number of functional groups. The smaller the weight average molecular weight of the polymerizable monomer and the greater the number of functional groups in the polymerizable monomer, the higher the photocuring efficiency. In an implementation, compounds with at least three functional groups in the monomer may have a small weight average molecular weight and a large number of functional groups, and thus they may be advantageous for maximizing photocuring efficiency.

In an implementation, the polymerizable monomer may include a mixture of two (or more) types of compounds. In an implementation, the two types of compounds may each independently be a compound containing three or more functional groups. In an implementation, the polymerizable monomer may be a mixture of a polymerizable compound including 3 functional groups and a polymerizable compound including 4 to 6 functional groups. In an implementation, the polymerizable monomer may have the above mixed composition, and photocuring efficiency may be maximized while maintaining the above-described color characteristics, making it easy to form a low-temperature curing pattern.

In an implementation, the two types of compounds may be mixed with each other in a weight ratio of about 1:1. Mixing the above two types of compounds at the same weight ratio may help ensure that low-temperature curing patternability may be most improved.

In an implementation, the polymerizable compound including the three functional groups may be represented by Chemical Formula 1.

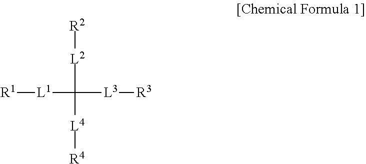

In Chemical Formula 1, L¹ to L⁴ may each independently be or include, e.g., a substituted or unsubstituted C1 to C20 alkylene group, a substituted or unsubstituted C1 to C20 oxyalkylene group, or a combination thereof.

R¹ to R⁴ may each independently be or include, e.g., hydrogen, a hydroxy group, epoxy group, or a substituted or unsubstituted (meth)acrylate group. In an implementation, three of R¹ to R⁴ may be an epoxy group or a substituted or unsubstituted (meth)acrylate group.

In an implementation, the compound including 4 to 6 functional groups may include pentaerythritoltetra(meth)acrylate, pentaerythritolhexa(meth)acrylate, dipentaerythritolpenta(meth)acrylate, dipentaerythritolhexa(meth)acrylate, or a combination thereof.

In an implementation, the polymerizable monomer may be included in a larger amount than or relative to the binder resin. Some photosensitive resin compositions for a color filter may include a binder resin in a larger amount than a polymerizable monomer. In an implementation, the photosensitive resin composition according to some embodiments, which may be applied to a micro OLED display device including WOLED deposited on a silicon wafer rather than a glass substrate or a polyimide substrate as a light source, may use low-temperature curing, and a case of including the polymerizable monomer in a larger amount than the binder resin may be more advantageous in improving patternability. In an implementation, the polymerizable monomer may be included in a larger amount than the binder resin, and the polymerizable monomer may be sufficiently polymerized with a photopolymerization initiator to be described later during the exposure in the low temperature pattern forming process, resultantly forming a pattern with excellent heat resistance, light resistance, and chemical resistance in the low-temperature process of about 100° C. or lower. Some other color filters for a liquid crystal display (LCD) may use a resist to form a pattern of about 100 μm, which may be too large a size to be used for a micro OLED display device. In an implementation, the contents of the polymerizable monomer and the binder resin may be controlled, and also, a content of the photopolymerization initiator to be described below to implement micro-patterning and achieve low-temperature curing may also be controlled.

In an implementation, polymerizable monomer may be treated with an acid anhydride to provide excellent developability.

The polymerizable monomer may be included in an amount of about 1 wt % to about 10 wt %, e.g., about 1 wt % to about 5 wt %, based on a total weight of the photosensitive resin composition. Including the polymerizable monomer within the ranges may help ensure that sufficient curing may occur in the low temperature pattern forming process, achieving excellent reliability, heat resistance of a pattern, light resistance, and chemical resistance, resolution, and adhesion.

### (D) Polymerization Initiator

The photosensitive resin composition according to some embodiments may include a polymerization initiator. In an implementation, the polymerization initiator may be included in an amount of about 0.65 wt % to about 1.3 wt %, e.g., about 0.65 wt % to about 1.0 wt %, based on a total weight of the photosensitive resin composition. Maintaining the content of the polymerization initiator within the above ranges, an optimal pattern can be formed in a low temperature curing process, together with the aforementioned composition of the polymerizable monomer, binder resin, and colorant. Including a polymerization initiator in an amount outside the above content ranges together with the aforementioned composition of the polymerizable monomer, binder resin, and colorant, patternability could be greatly reduced during the low-temperature curing process.

The polymerization initiator may include, e.g., an acetophenone compound, a benzophenone compound, a thioxanthone compound, a benzoin compound, a triazine compound, an oxime compound, or a combination thereof.

Examples of the acetophenone compound may include 2,2′-diethoxy acetophenone, 2,2′-dibutoxy acetophenone, 2-hydroxy-2-methylpropinophenone, p-t-butyltrichloro acetophenone, p-t-butyldichloro acetophenone, 4-chloro acetophenone, 2,2′-dichloro-4-phenoxy acetophenone, 2-methyl-1-(4-(methylthio)phenyl)-2-morpholinopropan-1-one, 2-benzyl-2-dimethylamino-1-(4-morpholinophenyl)-butan-1-one, or the like.

Examples of the benzophenone compound may include benzophenone, benzoyl benzoate, benzoyl methyl benzoate, 4-phenyl benzophenone, hydroxy benzophenone, acrylated benzophenone, 4,4′-bis(dimethyl amino)benzophenone, 4,4′-bis(diethylamino)benzophenone, 4,4′-dimethylaminobenzophenone, 4,4′-dichlorobenzophenone, 3,3′-dimethyl-2-methoxybenzophenone, and the like.

Examples of the thioxanthone compound may include thioxanthone, 2-methylthioxanthone, isopropyl thioxanthone, 2,4-diethyl thioxanthone, 2,4-diisopropyl thioxanthone, 2-chlorothioxanthone, and the like.

Examples of the benzoin compound may include benzoin, benzoin methyl ether, benzoin ethyl ether, benzoin isopropyl ether, benzoin isobutyl ether, benzyl dimethyl ketal, and the like.

Examples of the triazine compound may include 2,4,6-trichloro-s-triazine, 2-phenyl 4,6-bis(trichloromethyl)-s-triazine, 2-(3′, 4′-dimethoxystyryl)-4,6-bis(trichloromethyl)-s-triazine, 2-(4′-methoxynaphthyl)-4,6-bis(trichloromethyl)-s-triazine, 2-(p-methoxyphenyl)-4,6-bis(trichloromethyl)-s-triazine, 2-(p-tolyl)-4,6-bis(trichloro methyl)-s-triazine, 2-biphenyl 4,6-bis(trichloro methyl)-s-triazine, bis(trichloromethyl)-6-styryl-s-triazine, 2-(naphthol-yl)-4,6-bis(trichloromethyl)-s-triazine, 2-(4-methoxynaphthol-yl)-4,6-bis(trichloromethyl)-s-triazine, 2-4-bis(trichloromethyl)-6-piperonyl-s-triazine, 2-4-bis(trichloromethyl)-6-(4-methoxystyryl)-s-triazine, and the like.

Examples of the oxime compound may include an O-acyloxime-bed compound, 2-(O-benzoyloxime)-1-[4-(phenylthio)phenyl]-1,2-octanedione, 1-(o-acetyloxime)-1-[9-ethyl-6-(2-methylbenzoyl)-9H-carbazol-3-yl]ethanone, 0-ethoxycarbonyl-α-oxyamino-1-phenylpropan-1-one, and the like. Examples of the O-acyloxime compound may be 1,2-octanedione, 2-dimethylamino-2-(4-methylbenzyl)-1-(4-morpholin-4-yl-phenyl)-butan-1-one, 1-(4-phenylsulfanyl phenyl)-butane-1,2-dione2-oxime-O-benzoate, 1-(4-phenylsulfanyl phenyl)-octane-1,2-dione2-oxime-O-benzoate, 1-(4-phenylsulfanyl phenyl)-octan-1-oneoxime-O-acetate and 1-(4-phenylsulfanyl phenyl)-butan-1-oneoxime-O-acetate, and the like.

In addition to the above compounds, the photopolymerization initiator may include, e.g., a carbazole compound, a diketone compound, a sulfonium borate compound, a diazo compound, an imidazole compound, and a biimidazole compound.

### (E) Solvent

The solvent may be a material that is compatible with, but does not react with, the pigment dispersion including the colorant, the binder resin, the polymerizable monomer, and the polymerization initiator.

Examples of the solvent may include alcohols such as methanol, ethanol, and the like; ethers such as dichloroethylether, n-butylether, diisoamylether, methylphenylether, tetrahydrofuran, and the like; glycolethers such as ethylene glycolmonomethylether, ethylene glycolmonoethylether, ethylene glycoldimethylether, and the like; cellosolve acetates such as methylcellosolveacetate, ethylcellosolveacetate, diethylcellosolveacetate, and the like; carbitols such as methylethylcarbitol, diethylcarbitol, diethylene glycolmonomethylether, diethylene glycolmonoethylether, diethylene glycoldimethylether, diethylene glycolethylmethylether, diethylene glycoldiethylether, and the like; propylene glycolalkyletheracetates such as propylene glycolmethyletheracetate, propylene glycolpropyletheracetate, and the like; aromatic hydrocarbons such as toluene, xylene, and the like; ketones such as methylethylketone, cyclohexanone, 4-hydroxy-4-methyl-2-pentanone, methyl-n-propylketone, methyl-n-butylketone, methyl-n-amylketone, 2-heptanone, and the like; saturated aliphatic monocarboxylic acid alkyl esters such as ethyl acetate, n-butyl acetate, isobutyl acetate, and the like; lactate esters such as methyl lactate, ethyl lactate, and the like; oxyacetate alkyl esters such as methyl oxyacetate, ethyl oxyacetate, butyl oxyacetate, and the like; alkoxy acetate alkyl esters such as methyl methoxy acetate, ethyl methoxy acetate, butyl methoxy acetate, methyl ethoxy acetate, ethyl ethoxy acetate, and the like; 3-oxypropionate alkyl esters such as methyl 3-oxypropionate, ethyl 3-oxypropionate, and the like; 3-alkoxy propionate alkyl esters such as 3-methoxy methyl propionate, 3-methoxy ethyl propionate, 3-ethoxy ethyl propionate, 3-ethoxy methyl propionate, and the like; 2-oxypropionate alkyl esters such as 2-oxymethyl propionate, 2-oxyethyl propionate, propyl 2-oxypropionate, and the like; 2-alkoxypropionate alkylester such as 2-methoxymethyl propionate, 2-methoxyethyl propionate, 2-ethoxyethyl propionate, 2-ethoxymethyl propionate, and the like; 2-oxy-2-methylpropionate ester such as 2-oxy-2-methylmethyl propionate, 2-oxy-2-methylethyl propionate, and the like, monooxymonocarboxylic acid alkyl esters of alkyl 2-alkoxy-2-methylpropionate such as 2-methoxy-2-methylmethyl propionate, 2-ethoxy-2-methylethyl propionate, and the like; esters such as 2-hydroxyethyl propionate, 2-hydroxy-2-methyl ethyl propionate, hydroxyl ethyl acetate, 2-hydroxy-3-methyl ethyl butanoate, and the like; ketone acid esters such as ethyl pyruvate, and the like. In an implementation, a high boiling point solvent such as N-methylformamide, N,N-dimethyl formamide, N-methylformanilide, N-methylacetamide, N,N-dimethyl acetamide, N-methylpyrrolidone, dimethylsulfoxide, benzylethylether, dihexylether, acetylacetone, isophorone, caproic acid, caprylic acid, 1-octanol, 1-nonanol, benzylalcohol, benzyl acetate, ethyl benzoate, diethyl oxalate, diethyl maleate, γ-butyrolactone, ethylene carbonate, propylene carbonate, phenyl cellosolve acetate, or the like may be also used.

In an implementation, considering compatibility and reactivity, glycolethers such as ethylene glycolmonoethylether, ethylene glycoldimethylether, ethylene glycoldiethylether, diethylene glycolethylmethylether, or the like; ethylene glycolalkyletheracetates such as ethylcellosolveacetate, or the like; esters such as 2-hydroxyethyl propionate, or the like; carbitols such as diethylene glycolmonomethylether, or the like; propylene glycolalkyletheracetates such as propylene glycolmonomethyl ether acetate, propylene glycolpropyletheracetate, or the like may be used.

The solvent may be included in a balance amount, e.g., about 0.1 wt % to about 10 wt %, about 0.1 wt % to about 5 wt %, or about 0.1 wt % to about 3 wt %, based on a total weight of the photosensitive resin composition. Including the solvent within the above ranges may help ensure that the photosensitive resin composition has an appropriate viscosity and thus the processability in manufacturing the photosensitive resin layer is improved.

### (F) Other Additives

In an implementation, the photosensitive resin composition may further include an additive, e.g., malonic acid, 3-amino-1,2-propanediol, a silane coupling agent, a leveling agent, a surfactant, or a combination thereof, but does not include an antioxidant.

The photosensitive resin composition according to some embodiments may include the binder resin, colorant, polymerizable compound, polymerization initiator, and solvent of the aforementioned composition. If an antioxidant were to be further included, the photocuring reaction may not proceed completely, pattern formation may not complete during the low-temperature curing process, and thus high-resolution pattern formation may not be possible. Therefore, the photosensitive resin composition according to some embodiments may not include an antioxidant, e.g., has an antioxidant-free composition.

The silane coupling agent may have a reactive substituent of, e.g., a vinyl group, a carboxyl group, a methacryloxy group, an isocyanate group, an epoxy group, or the like, in order to improve close-contacting properties with a substrate.

Examples of the silane coupling agent may include trimethoxysilylbenzoic acid, γ-methacryloxypropyltrimethoxysilane, vinyltriacetoxysilane, vinyltrimethoxysilane, γ-isocyanatepropyltriethoxysilane, γ-glycidoxypropyltrimethoxysilane, 3-(3,4-epoxycyclohexyl)ethyltrimethoxysilane, and the like, and these may be used alone or in a mixture of two or more.

The silane coupling agent may be included in an amount of about 0.01 to about 10 parts by weight, based on 100 parts by weight of the photosensitive resin composition. Including the silane coupling agent within the above range, adhesion, storage, or the like may be improved.

In an implementation, the photosensitive resin composition may further include a surfactant, e.g., a fluorine surfactant or a silicone surfactant, in order to improve coating properties and prevent defect generation.

Examples of the fluorine surfactant may include a commercially available fluorine surfactant such as BM-1000®, BM-1100®, and the like of BM Chemie Inc.; MEGAFACE F 142D®, MEGAFACE F 172®, MEGAFACE F 173®, MEGAFACE F 183®, MEGAFACE F 554®, MEGAFACE F 556®, and the like of Dainippon Ink Kagaku Kogyo Co., Ltd.; FULORAD FC-135®, FULORAD FC-170C®, FULORAD FC-430®, FULORAD FC-431®, and the like of SUMITOMO 3M Co., Ltd.; SURFLON S-112®, SURFLON S-113®, SURFLON S-131®, SURFLON S-141®, SURFLON S-145®, and the like of Asahi Glass Co., Ltd.; SH-28PA®, SH-190®, SH-193®, SZ-6032®, SF-8428®, and the like of Toray Silicone Co., Ltd.

The silicone surfactant may include a commercial silicone surfactant such as BYK-307, BYK-333, BYK-361N, BYK-051, BYK-052, BYK-053, BYK-067A, BYK-077, BYK-301, BYK-322, BYK-325, and the like of BYK Chem.

The surfactant may be included in an amount of about 0.001 parts by weight to about 5 parts by weight, based on 100 parts by weight of the photosensitive resin composition. Including the surfactant within this range may help ensure that coating uniformity may be secured, a stain may not be produced, and wetting on an IZO substrate or a glass substrate is improved.

In an implementation, the photosensitive resin composition may include other additives, e.g., a stabilizer in a predetermined amount unless they deteriorate properties of the photosensitive resin composition.

The photosensitive resin composition according to some embodiments may be either positive or negative. In an implementation, the composition may be negative to completely remove residues in regions where a pattern is exposed after exposing and developing the composition having light blocking properties.

Some embodiments may provide a photosensitive resin layer manufactured by low-temperature curing, exposure, and development of the aforementioned photosensitive resin composition. Compared to an LCD process, there may be a difference in that the post-curing (post-baking) process is unnecessary.

A method for manufacturing the photosensitive resin layer may be as follows.

### (1) Coating and Film Formation (Low-Temperature Curing)

The photosensitive resin composition may be coated to a desired thickness on a substrate such as a glass substrate or ITO substrate, or the like, which may undergo a predetermined pretreatment, using a spin or slit coating method, a roll coating method, a screen-printing method, an applicator method, or the like, and may be heated at 100° C. or lower, e.g., 85° C., for 1 minute to 10 minutes to remove a solvent and to form a photosensitive resin layer. Through this step, it may be possible to improve image quality and unevenness.

### (2) Exposure

After disposing a mask to form a necessary pattern on the obtained photosensitive resin layer, exposure may be performed by irradiating an actinic ray of i-line. As a light source used for irradiation, a low-pressure mercury lamp, a high-pressure mercury lamp, an ultra-high pressure mercury lamp, a metal halide lamp, an argon gas laser, or the like may be used, and in some cases, an X-ray, an electron beam, or the like may be used.

The exposure dose may vary depending on the type, mixing amount, and dry film thickness of each component of the composition, but may be less than or equal to about 500 mJ/cm² (based on a 365 nm sensor) when using a high-pressure mercury lamp. In an implementation, the exposure dose may exceed about 500 mJ/cm² (by 365 nm sensor). Through this step, fine adjustment of pixel size is possible, enabling high-resolution implementation.

### (3) Development

In the development method, following the exposure step, an alkaline aqueous solution may be used as a developer to dissolve and remove unnecessary portions, leaving only the exposed portions remaining to form a pattern. Through this step, a profile can be formed to realize high resolution, and color uniformity can be secured to improve clarity.

Some embodiments may provide a display device including the photosensitive resin layer.

The display device may be a micro organic light emitting diode (OLED) display device.

The micro organic light emitting diode (OLED) display device may include an OLED substrate on a silicon wafer and a color filter layer stacked on the OLED substrate and converting white light generated from the OLED substrate into a plurality of color lights. In an implementation, the color filter layer may include a red color filter, a green color filter, and a blue color filter.

In an implementation, the micro organic light emitting diode (OLED) display device may include an OLED substrate on a silicon wafer, an inorganic layer on the OLED substrate, an adhesive protection layer on the inorganic layer, and a color filter layer on the inorganic layer and converting white light generated from the OLED substrate to a plurality of color lights. In an implementation, the color filter may include a red color filter, a green color filter, and a blue color filter.

In an implementation, the photosensitive resin composition according to some embodiments may be a green photosensitive resin composition, and the green color filter in the micro OLED display device may be a low-temperature cured layer of the green photosensitive resin composition.

On some OLED substrates, OLEDs may be deposited on a glass or polyimide substrate. The micro OLED display device according to some embodiments may have OLEDs deposited on a silicon wafer, which may be more advantageous in implementing a micro display. These micro displays are in the spotlight as next-generation displays, and the micro displays are expected to be applied to devices such as MR.

In an implementation, the micro OLED display device may further include a micro lens array. The micro lens array may be on the adhesive protection layer and surround the color filter layer.

A micro OLED display device with the above structure, which may be driven on a pixel basis due to deposition of WOLED on a highly integrated silicon wafer and in which a transmission wavelength may be easy to control through a color filter layer patterned with a resolution of about 3 μm or less, may advantageously secure high color reproduction and high resolution.

In an implementation, the adhesive protection layer may have a thickness of less than or equal to about 1 μm. Herein, the effects may be further maximized.

In an implementation, the color filter layer may have a thickness of about 1.1 μm to about 1.6 μm.

Maintaining the thickness of the color filter layer within the ranges may help ensure that it may be more advantageous to implement a micro OLED display device.

In an implementation, the inorganic layer may have a thickness of less than or equal to about 2 μm. Even in WOLED, light may not always diffuse in a perpendicular direction to an OLED substrate, and color mixing of red, green, and blue could occur. In order to prevent this color mixing, the inorganic layer could be deposited on the OLED substrate. The color mixing may not be completely prevented by depositing the inorganic layer, and the inorganic layer may be thinned, e.g., a thickness of the inorganic layer may be controlled to about 2 μm or less to prevent the fine light leakage.

In an implementation, the photosensitive resin composition according to some embodiments, as aforementioned, may be formed into a film only through low-temperature curing (about 100° C.) and i-line photocuring during the prebaking, and there may be a huge difference in resolution to be realized, compared with other display devices.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

### EXAMPLES

### (Preparation of Photosensitive Resin Composition)

### Examples 1 to 23 and Comparative Examples 1 to 14

With each composition shown in Tables 1 to 5, a polymerization initiator was dissolved in a solvent and then, stirred at ambient temperature for 2 hours. A binder resin and a polymerizable monomer were added thereto and then, stirred for 1 hour at ambient temperature. After adding other additives and a colorant thereto and then, stirring for 1 hour at ambient temperature, the obtained solution was stirred for 2 hours. The solution was filtered three times to remove impurities, preparing a photosensitive resin composition.

TABLE 1
(unit: wt %)

| | | Ex. 1 | Ex. 2 | Ex. 3 | Ex. 4 | Ex. 5 | Ex. 6 | Ex. 7 | Ex. 8 | Ex. 9 |
|---|---|---|---|---|---|---|---|---|---|---|
| (A) Binder | (A-1) | 2.43 | 2.43 | 2.43 | 2.43 | — | — | — | 2.39 | 4.03 |
| resin | (A-2) | — | — | — | — | 2.43 | — | — | — | — |
| | (A-3) | — | — | — | — | — | 2.43 | — | — | — |
| (B) | (B-1) | 53.32 | 53.32 | 53.32 | 53.32 | 53.32 | 53.32 | 53.32 | 53.32 | 53.41 |
| Colorant | (B-2) | 38.63 | 38.63 | 38.63 | 38.63 | 38.63 | 38.63 | 38.63 | 38.63 | 36.73 |
| (C) | (C-1) | 1.87 | 3.74 | 1.87 | — | 1.87 | 1.87 | 1.87 | 3.68 | 3.62 |
| Polymerizable | (C-2) | 1.87 | — | — | 1.87 | 1.87 | 1.87 | 1.87 | — | — |
| monomer | (C-3) | — | — | 1.87 | 1.87 | — | — | — | — | — |
| (D) Polymerization | | 0.70 | 0.70 | 0.70 | 0.70 | 0.70 | 0.70 | 0.70 | 0.78 | 0.77 |
| initiator | | | | | | | | | | |
| (E) Solvent | | 0.80 | 0.80 | 0.80 | 0.80 | 0.80 | 0.80 | 3.23 | 0.82 | 1.05 |
| (F) Other | (F-1) | 0.20 | 0.20 | 0.20 | 0.20 | 0.20 | 0.20 | 0.20 | 0.20 | 0.20 |
| additives | (F-2) | 0.18 | 0.18 | 0.18 | 0.18 | 0.18 | 0.18 | 0.18 | 0.18 | 0.20 |
| | (F-3) | — | — | — | — | — | — | — | — | — |

TABLE 2
(unit: wt %)

| | | Ex. 10 | Ex. 11 | Ex. 12 | Ex. 13 | Ex. 14 | Ex. 15 | Ex. 16 | Ex. 17 |
|---|---|---|---|---|---|---|---|---|---|
| (A) Binder | (A-1) | 2.43 | 2.43 | 2.43 | 2.43 | 2.43 | 2.43 | — | 2.43 |
| resin | (A-2) | — | — | — | — | — | — | — | — |
| | (A-3) | — | — | — | — | — | — | — | — |
| (B) Colorant | (B-1) | 50.32 | 50.32 | 50.32 | 50.32 | 47.32 | 47.32 | 47.32 | 47.32 |
| | (B-2) | 36.63 | 36.63 | 36.63 | 36.63 | 34.63 | 34.63 | 34.63 | 34.63 |
| (C) | (C-1) | 1.87 | 3.74 | 1.87 | — | 1.87 | 3.74 | 1.87 | — |
| Polymerizable | (C-2) | 1.87 | — | — | 1.87 | 1.87 | — | — | 1.87 |
| monomer | (C-3) | — | — | 1.87 | 1.87 | — | — | 1.87 | 1.87 |
| (D) Polymerization | | 0.70 | 0.70 | 0.70 | 0.70 | 0.70 | 0.70 | 0.70 | 0.70 |
| initiator | | | | | | | | | |
| (E) Solvent | | 5.80 | 5.80 | 5.80 | 5.80 | 10.80 | 10.80 | 10.80 | 10.80 |
| (F) Other | (F-1) | 0.20 | 0.20 | 0.20 | 0.20 | 0.20 | 0.20 | 0.20 | 0.20 |
| additives | (F-2) | 0.18 | 0.18 | 0.18 | 0.18 | 0.18 | 0.18 | 0.18 | 0.18 |
| | (F-3) | — | — | — | — | — | — | — | — |

TABLE 3
(unit: wt %)

| | | Ex. 18 | Ex. 19 | Ex. 20 | Ex. 21 | Ex. 22 | Ex. 23 |
|---|---|---|---|---|---|---|---|
| (A) Binder | (A-1) | 2.43 | 2.43 | 2.43 | 2.43 | 2.43 | 2.43 |
| resin | (A-2) | — | — | — | — | — | — |
| | (A-3) | — | — | — | — | — | — |
| (B) Colorant | (B-1) | 47.32 | 47.32 | 47.32 | 47.32 | 47.32 | 47.32 |
| | (B-2) | 34.63 | 34.63 | 34.63 | 34.63 | 34.63 | 34.63 |
| (C) Polymerizable | (C-1) | 1.87 | 1.87 | 1.87 | 1.87 | 1.87 | 1.87 |
| monomer | (C-2) | 1.87 | 1.87 | 1.87 | 1.87 | 1.87 | 1.87 |
| | (C-3) | — | — | — | — | — | — |
| (D) Polymerization initiator | | 0.80 | 0.90 | 1.0 | 1.1 | 1.2 | 1.3 |
| (E) Solvent | | 10.70 | 10.60 | 10.50 | 10.40 | 10.30 | 10.20 |
| (F) Other | (F-1) | 0.20 | 0.20 | 0.20 | 0.20 | 0.20 | 0.20 |
| additives | (F-2) | 0.18 | 0.18 | 0.18 | 0.18 | 0.18 | 0.18 |
| | (F-3) | — | — | — | — | — | — |

TABLE 4
(unit: wt %)

| | | Comp. | Comp. | Comp. | Comp. | Comp. | Comp. |
|---|---|---|---|---|---|---|---|
| | | Ex. 1 | Ex. 2 | Ex. 3 | Ex. 4 | Ex. 5 | Ex. 6 |
| (A) Binder | (A-1) | 2.47 | 6.45 | 2.43 | 2.42 | 2.43 | 2.43 |
| resin | (A-2) | — | — | — | — | — | — |
| | (A-3) | — | — | — | — | — | — |
| (B) Colorant | (B-1) | 53.32 | 33.46 | 53.32 | 53.32 | 33.46 | 53.32 |
| | (B-2) | 38.63 | 44.89 | 38.63 | 38.63 | 58.49 | 25.03 |
| (C) | (C-1) | 3.81 | 5.81 | 1.87 | 1.86 | 1.87 | 1.87 |
| Polymerizable | (C-2) | — | — | 1.87 | 1.86 | 1.87 | 1.87 |
| monomer | (C-3) | — | — | — | — | — | — |
| (D) Polymerization | | 0.62 | 0.66 | 0.70 | 0.70 | 0.70 | 0.70 |
| initiator | | | | | | | |
| (E) Solvent | | 0.77 | 5.37 | 0.80 | 0.80 | 0.80 | 0.80 |
| (F) Other | (F-1) | 0.20 | 0.20 | 0.20 | 0.20 | 0.20 | 0.20 |
| additives | (F-2) | 0.18 | 3.16 | 0.18 | 0.18 | 0.18 | 0.18 |
| | (F-3) | — | — | 0.01 | 0.03 | — | — |

TABLE 5
(unit: wt %)

| | | Comp. | Comp. | Comp. | Comp. | Comp. | Comp. | Comp. | Comp. |
|---|---|---|---|---|---|---|---|---|---|
| | | Ex. 7 | Ex. 8 | Ex. 9 | Ex. 10 | Ex. 11 | Ex. 12 | Ex. 13 | Ex. 14 |
| (A) Binder | (A-1) | 2.47 | 2.47 | 2.43 | 2.42 | 2.43 | 2.43 | 2.43 | 2.42 |
| resin | (A-2) | — | — | — | — | — | — | — | — |
| | (A-3) | — | — | — | — | — | — | — | — |
| (B) Colorant | (B-1) | 50.32 | 47.32 | 50.32 | 47.32 | 46.46 | 46.32 | 50.32 | 47.32 |
| | (B-2) | 36.63 | 34.63 | 36.63 | 34.63 | 33.49 | 33.03 | 36.63 | 34.63 |
| (C) | (C-1) | 3.81 | 3.81 | 1.87 | 1.86 | 1.87 | 1.87 | 1.87 | 1.86 |
| Polymerizable | (C-2) | — | — | 1.87 | 1.86 | 1.87 | 1.87 | 1.87 | 1.86 |
| monomer | (C-3) | — | — | — | — | — | — | — | — |
| (D) Polymerization | | 0.62 | 0.63 | 0.70 | 0.70 | 0.70 | 0.70 | 1.4 | 1.4 |
| initiator | | | | | | | | | |
| (E) Solvent | | 5.77 | 10.76 | 5.79 | 10.80 | 12.80 | 13.40 | 5.1 | 10.13 |
| (F) Other | (F-1) | 0.20 | 0.20 | 0.20 | 0.20 | 0.20 | 0.20 | 0.20 | 0.20 |
| additives | (F-2) | 0.18 | 0.18 | 0.18 | 0.18 | 0.18 | 0.18 | 0.18 | 0.18 |
| | (F-3) | — | — | 0.01 | 0.03 | — | — | — | — |

### (A) Binder Resin

(A-1) Acrylic binder resin (SP-RY38; Showa Denko) (69 KOHmg/g, 6,000 g/mol, 370 g/mol)
(A-1) Acrylic binder resin (SP-RY38; Showa Denko) (69 KOHmg/g, 6,000 g/mol, 370 g/mol)
(A-1) Acrylic binder resin (SP-RY38; Showa Denko) (69 KOHmg/g, 6,000 g/mol, 370 g/mol)

### (B) Colorant

(B-1) Green pigment dispersion (Sanyo, G58)
(B-2) Yellow pigment dispersion (Sanyo, Y139)

### (C) Polymerizable Monomer

(C-1) pentaerythritol triacrylate (PE-3A, Gongyoungsa Co., Ltd.)
(C-2) Dipentaerythritol hexa(meth)acrylate (DPHA, Nippon Kayaku Co. Ltd.)
(C-3) Compound represented by Chemical Formula A (M200, Miwon Chemical Co., Ltd.)

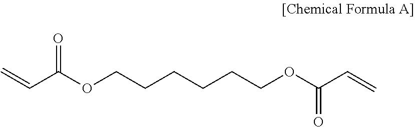 [SMILES: C=CC(=O)OCCCCCCOC(=O)C=C]

### (D) Polymerization Initiator

Oxime initiator (SPI-03, Samyang Corp.)

### (E) Solvent

Propylene glycol monomethyl ether acetate (PGMEA, Daicel Co., Ltd.)

### (F) Other Additives

(F-1) Leveling agent (F-556, DIC Co., Ltd.)
(F-2) Silane coupling agent (KBM503, ShinEtsu)

### (F-3) Antioxidant (2-Methylhydroquinone, JHChem)

### Evaluation 1

The photosensitive compositions of Examples 1 to 23 and Comparative Examples 1 to 14 were respectively coated on an 8-inch silicon wafer at an rpm capable of reaching a predetermined thickness (1.5 μm) by using K-spin 8 (Track) equipment. Subsequently, the coated wafers were baked at 100° C. for 3 minutes or 85° C. for 6 minutes on a hot plate of the Track equipment and then, exposed for patterning by controlling an exposure dose with an i-line stepper made by Nikon Corp. Then, development proceeded to obtain a pattern. The obtained 1.6 μm pattern CD was measured by CD-SEM made by Hitachi, Ltd.

For evaluating color characteristics, patterns (substrates) were obtained in the same manner as above except that a glass wafer was used, wherein because a target thickness (1.5 μm) was accurately obtained, two substrates per sample were manufactured. A fine pattern chromaticity meter (LCF) was used to measure colors of the patterns.

The experiment results are provided in Tables 6 and 7.

TABLE 6

| | Exposure | | Exposure | | Exposure |
|---|---|---|---|---|---|
| | dose | | dose | | dose |
| | (1,000 ms) | | (1,000 ms) | | (1,000 ms) |
| | pattern | | pattern | | pattern |
| | size(μm) | | size(μm) | | size(μm) |
| Example 1 | 1.67 | Example 10 | 1.70 | Example 19 | 1.98 |
| Example 2 | 1.69 | Example 11 | 1.71 | Example 20 | 1.98 |
| Example 3 | 1.69 | Example 12 | 1.70 | Example 21 | 1.99 |
| Example 4 | 1.70 | Example 13 | 1.72 | Example 22 | 1.99 |
| Example 5 | 2.03 | Example 14 | 1.92 | Example 23 | 1.99 |
| Example 6 | 2.04 | Example 15 | 1.92 | | |
| Example 7 | 2.05 | Example 16 | 1.93 | | |
| Example 8 | 2.10 | Example 17 | 1.95 | | |
| Example 9 | 2.15 | Example 18 | 1.98 | | |
| Comparative | 2.58 | Comparative | 2.73 | Comparative | 2.98 |
| Example 1 | | Example 7 | | Example 13 | |
| Comparative | 2.54 | Comparative | 2.72 | Comparative | 3.02 |
| Example 2 | | Example 8 | | Example 14 | |
| Comparative | 2.62 | Comparative | 2.77 | | |
| Example 3 | | Example 9 | | | |
| Comparative | 2.68 | Comparative | 2.79 | | |
| Example 4 | | Example 10 | | | |
| Comparative | 2.59 | Comparative | 2.71 | | |
| Example 5 | | Example 11 | | | |
| Comparative | 2.57 | Comparative | 2.70 | | |
| Example 6 | | Example 12 | | | |

TABLE 7

| | | | | Full | | | | |
|---|---|---|---|---|---|---|---|---|
| | Full width | | | width at | | | Full width | |
| | at half | | | half | | | at half | |
| | maximum | | | maximum | | | maximum | |
| | (FWHM) | Transmittance | | (FWHM) | Transmittance | | (FWHM) | Transmittance |
| | (nm) | (%) at 630 nm | | (nm) | (%) at 630 nm | | (nm) | (%) at 630 nm |
| Ex. 1 | 99 | 6.9 | Ex. 10 | 97 | 7.0 | Ex. 19 | 97 | 6.8 |
| Ex. 2 | 99 | 7.0 | Ex. 11 | 98 | 7.0 | Ex. 20 | 97 | 6.8 |
| Ex. 3 | 99 | 7.0 | Ex. 12 | 97 | 7.1 | Ex. 21 | 96 | 6.7 |
| Ex. 4 | 99 | 7.1 | Ex. 13 | 98 | 7.1 | Ex. 22 | 96 | 6.7 |
| Ex. 5 | 98 | 7.3 | Ex. 14 | 96 | 6.8 | Ex. 23 | 97 | 6.8 |
| Ex. 6 | 98 | 7.3 | Ex. 15 | 96 | 6.7 | | | |
| Ex. 7 | 98 | 7.3 | Ex. 16 | 96 | 6.7 | | | |
| Ex. 8 | 97 | 7.6 | Ex. 17 | 95 | 6.6 | | | |
| Ex. 9 | 97 | 7.8 | Ex. 18 | 96 | 6.6 | | | |
| Comp. | 106 | 11.2 | Comp. | 108 | 11.5 | Comp. Ex. | 110 | 13.4 |
| Ex. 1 | | | Ex. 7 | | | 13 | | |
| Comp. | 107 | 11.2 | Comp. | 108 | 11.5 | Comp. Ex. | 112 | 13.7 |
| Ex. 2 | | | Ex. 8 | | | 14 | | |
| Comp. | 111 | 18.1 | Comp. | 110 | 18.6 | | | |
| Ex. 3 | | | Ex. 9 | | | | | |
| Comp. | 113 | 18.9 | Comp. | 115 | 19.2 | | | |
| Ex. 4 | | | Ex. 10 | | | | | |
| Comp. | 108 | 11.0 | Comp. | 110 | 11.2 | | | |
| Ex. 5 | | | Ex. 11 | | | | | |
| Comp. | 109 | 11.1 | Comp. | 111 | 11.3 | | | |
| Ex. 6 | | | Ex. 12 | | | | | |

Referring to Tables 6 and 7, the photosensitive resin compositions according to the Examples, although cured at a low temperature, realized a fine pattern and secured a wide color gamut due to excellent color characteristics.

By way of summation and review, micro OLED display panels may have about ten times smaller pixels than other OLED display panels, and there could be issues in precisely forming red (R)/green (G)/blue (B) light emitting layers through FMM (Fine Metal Mask) technology. If some liquid crystal displays were to be applied to the devices such as VR, AR, and the like, the color filters could have too large a pattern size to increase resolution.

Accordingly, in order to achieve high resolution of about 4,000 ppi or more, OLEDos (OLED on Silicon) technology has been considered. This corresponding technology may use OLED deposited on a silicon wafer as a back light to pattern color filters thereon. The color filters used in some other liquid crystal displays may use a pattern of about 100 μm on a glass and may be cured through exposure and post-baking at a high temperature of about 230° C. or higher, the color filters on OLEDos, e.g., because the high-temperature process is not possible due to OLED, may be cured at a at a low temperature and also, micro-patterned to increase resolution. In order to be applied to the VR, AR, and MR devices with a small size, the micro-patterning may help achieve the desired resolution.

The curing may proceed at a low temperature (about 100° C. or lower), and color filters formed of some other materials may have issues in forming a high-resolution pattern and securing color gamut and a viewing angle.

One or more embodiments may provide a photosensitive resin composition that may be sufficiently cured even at low temperatures, may have excellent high-resolution pattern formation properties, and may help further ensure high color gamut and viewing angles.

The photosensitive resin composition according to some embodiments may be cured at a low temperature of less than or equal to about 100° C., may help secure high resolution through the implementation of fine patterns, and may have excellent spectral characteristics, making it possible to secure a wide color gamut. It may be suitable for application to micro OLED display devices in that it may have excellent color characteristics and may create fine patterns with only temperature and photocuring (i-line exposure) while pre-baking at less than or equal to about 100° C.

Example embodiments have been disclosed herein, and although specific terms are employed, they are used and are to be interpreted in a generic and descriptive sense only and not for purposes of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. An antioxidant-free photosensitive resin composition, comprising:
a binder resin;
a colorant;
a polymerizable monomer;
a polymerization initiator; and
a solvent,
wherein:
the colorant is included in an amount of about 80 wt % to about 95 wt %, based on a total weight of the composition,
the polymerization initiator is included in an amount of about 0.65 wt % to about 1.3 wt %, based on a total weight of the composition,
the colorant comprises a green pigment and a yellow pigment, and
the green pigment is included in an amount of greater than or equal to about 50 wt %, based on a total weight of the colorant.

2. The antioxidant-free photosensitive resin composition as claimed in claim 1, wherein the green pigment and yellow pigment are each independently included in a form of a pigment dispersion.

3. The antioxidant-free photosensitive resin composition as claimed in claim 1, wherein the binder resin is an acrylic binder resin.

4. The antioxidant-free photosensitive resin composition as claimed in claim 3, wherein the acrylic binder resin has an acid value of greater than or equal to about 50 KOHm/g and a weight average molecular weight of less than or equal to about 7,000 g/mol.

5. The antioxidant-free photosensitive resin composition as claimed in claim 4, wherein the acrylic binder resin has a double bond equivalent weight of greater than or equal to about 360 g/mol.

6. The antioxidant-free photosensitive resin composition as claimed in claim 1, wherein the polymerizable monomer comprises a compound that comprises three or more functional groups.

7. The antioxidant-free photosensitive resin composition as claimed in claim 6, wherein:
the polymerizable monomer comprises a mixture of two different compounds, and
the two different compounds are each independently a compound comprising three or more functional groups.

8. The antioxidant-free photosensitive resin composition as claimed in claim 7, wherein the two different compounds are mixed in a weight ratio of about 1:1.

9. The antioxidant-free photosensitive resin composition as claimed in claim 1, wherein an amount of the polymerizable monomer included in the composition is larger than an amount of the binder resin included in the composition.

10. The antioxidant-free photosensitive resin composition as claimed in claim 1, wherein the photosensitive resin composition has a full width at half maximum (FWHM) of less than 105 nm.

11. The antioxidant-free photosensitive resin composition as claimed in claim 1, wherein the photosensitive resin composition has a transmittance of less than about 8% at 630 nm.

12. The antioxidant-free photosensitive resin composition as claimed in claim 1, wherein the photosensitive resin composition comprises:
about 1 wt % to about 5 wt % of the binder resin;
the about 80 wt % to about 95 wt % of the colorant;
about 1 wt % to about 10 wt % of the polymerizable monomer;
the about 0.65 wt % to about 1.3 wt % of the polymerization initiator; and
the solvent,
based on a total weight of the photosensitive resin composition.

13. The antioxidant-free photosensitive resin composition as claimed in claim 1, wherein the photosensitive resin composition further comprises malonic acid, 3-amino-1,2-propanediol, a silane coupling agent, a leveling agent, a surfactant, or a combination thereof.

14. A photosensitive resin layer manufactured using the photosensitive resin composition as claimed in claim 1.

15. A display device comprising the photosensitive resin layer as claimed in claim 14.

16. The display device as claimed in claim 15, wherein:
the display device is a micro OLED display device that comprises an OLED substrate on a silicon wafer and a color filter layer stacked on the OLED substrate, the color filter layer being configured to convert white light generated from the OLED substrate into a plurality of color lights, and
the color filter layer comprises a red color filter, a green color filter, and a blue color filter.

17. A method of manufacturing a photosensitive resin layer, the method comprising:
coating the photosensitive resin composition as claimed in claim 1 on a substrate;
prebaking at a temperature of about 100° C. or lower after coating;
exposing to i-line after the prebaking, and
developing after exposing.
